(19) United States
(12) Patent Application Publication
(10) Pub. No.: US 2024/0420021 A1
(43) Pub. Date: Dec. 19, 2024

(54) IR-DROP PREDICTION SYSTEM AND IR-DROP PREDICTION METHOD

(71) Applicant: SK hynix Inc., Icheon-si (KR)

(72) Inventor: Hyun Jun KIM, Icheon-si (KR)

(21) Appl. No.: 18/471,168

(22) Filed: Sep. 20, 2023

(30) Foreign Application Priority Data
Jun. 16, 2023 (KR) 10-2023-0077489

(51) Int. Cl. G06N 20/00; G06F 30/398

(52) U.S. Cl. CPC G06N 20/00; G06F 30/398

(57) ABSTRACT

According to an embodiment of the disclosure, an IR-drop prediction system includes a data frame generator configured to generate a raw data frame including IR-drop data for each of a plurality of instances in a designed circuit, a training performer configured to select input instances among the plurality of instances included in the raw data frame and perform training for an IR-drop prediction based on the IR-drop data for the input instances, and an IR-drop predictor configured to predict an IR-drop based on an IR-drop prediction model obtained according to a result of the training. The IR-drop data includes an IR-drop value of a corresponding instance and a plurality of IR-drop factors related to the IR-drop value, and the input instances have the IR-drop values greater than or equal to a preset value.

### CROSS-REFERENCE TO RELATED APPLICATION

The present application claims priority under 35 U.S.C. § 119(a) to Korean Patent Application No. 10-2023-0077489 filed on Jun. 16, 2023, in the Korean Intellectual Property Office, the disclosure of which is incorporated herein by reference it its entirety.

### BACKGROUND

### 1. Field of Invention

The present disclosure relates to an IR-drop prediction system and an IR-drop prediction method.

### 2. Description of Related Art

In an electronic circuit, a voltage drop (IR-drop) may occur along a conductor carrying a current, and the IR-drop may cause a decrease in voltage supply. Thus, the IR-drop is a factor that must be considered in circuit design.

When designing a circuit, the IR-drop may be predicted by performing a simulation using a software tool, and the circuit may be designed or modified using the results of the simulation.

### SUMMARY

Embodiments of the present disclosure provide an IR-drop prediction system and an IR-drop prediction method that improves IR-drop prediction performance and reduces training time for obtaining an IR-drop prediction model.

According to an embodiment of the present disclosure, an IR-drop prediction system includes a data frame generator configured to generate a raw data frame including IR-drop data for each of a plurality of instances in a designed circuit, a training performer configured to select input instances among the plurality of instances included in the raw data frame and perform training for an IR-drop prediction based on the IR-drop data for the input instances, and an IR-drop predictor configured to predict an IR-drop based on an IR-drop prediction model obtained according to a result of the training. The IR-drop data includes an IR-drop value of a corresponding instance and a plurality of IR-drop factors related to the IR-drop value, and the input instances have IR-drop values greater than or equal to a preset value.

According to an embodiment of the present disclosure, an IR-drop prediction method includes generating a raw data frame including IR-drop data for each of a plurality of instances in a designed circuit, generating an input data frame including IR-drop data for input instances by selecting the input instances from among the plurality of instances included in the raw data frame, performing training by inputting the input data frame to a machine learning model, and obtaining an optimized IR-drop prediction model based on a result of the training. The IR-drop data includes an IR-drop value of a corresponding instance and a plurality of IR-drop factors related to the IR-drop value, and the input instances have IR-drop values greater than or equal to a preset value.

According to the present technology, an IR-drop prediction system and an IR-drop prediction method that improve IR-drop prediction performance and reduce training time for obtaining an IR-drop prediction model are provided.

### BRIEF DESCRIPTION OF THE DRAWINGS

FIG. 1 is a block diagram illustrating an IR-drop prediction system according to an embodiment of the present disclosure.

FIG. 2 is a block diagram illustrating a data frame generator of FIG. 1.

FIG. 3 is a diagram illustrating a raw data frame generated in an IR-drop prediction system according to an embodiment of the present disclosure.

FIG. 4 is a diagram illustrating an example of a first raw data frame generated in an IR-drop prediction system according to an embodiment of the present disclosure.

FIG. 5 is a diagram illustrating tiles used to generate a data frame in an IR-drop prediction system according to an embodiment of the present disclosure.

FIG. 6 is a diagram illustrating an example of a second raw data frame generated in an IR-drop prediction system according to an embodiment of the present disclosure.

FIG. 7 is a graph illustrating an example of a method of determining a size of a tile in an IR-drop prediction system according to an embodiment of the present disclosure.

FIG. 8 is a graph illustrating another example of a method of determining a size of a tile in an IR-drop prediction system according to an embodiment of the present disclosure.

FIG. 9 is a block diagram illustrating a training performer of FIG. 1.

FIG. 10 is a diagram illustrating an example of an input data frame generated in an IR-drop prediction system according to an embodiment of the present disclosure.

FIG. 11 is a graph illustrating an example of a method of selecting an instance included in an input data frame in an IR-drop prediction system according to an embodiment of the present disclosure.

FIG. 12 is a graph illustrating another example of a method of selecting an instance included in an input data frame in an IR-drop prediction system according to an embodiment of the present disclosure.

FIG. 13 is a flowchart illustrating an IR-drop prediction method according to an embodiment of the present disclosure.

FIG. 14 is a flowchart illustrating an operation S1305 of FIG. 13 in more detail.

FIG. 15 is a flowchart illustrating operations S1405 and S1407 of FIG. 14 in more detail.

### DETAILED DESCRIPTION

Specific structural or functional descriptions of embodiments according to the concept of the present disclosure disclosed in the present specification or application are illustrated only to describe the embodiments according to the concept of the present disclosure. The embodiments according to the concept of the present disclosure may be carried out in various forms and are not limited to the embodiments described in the present specification or application.

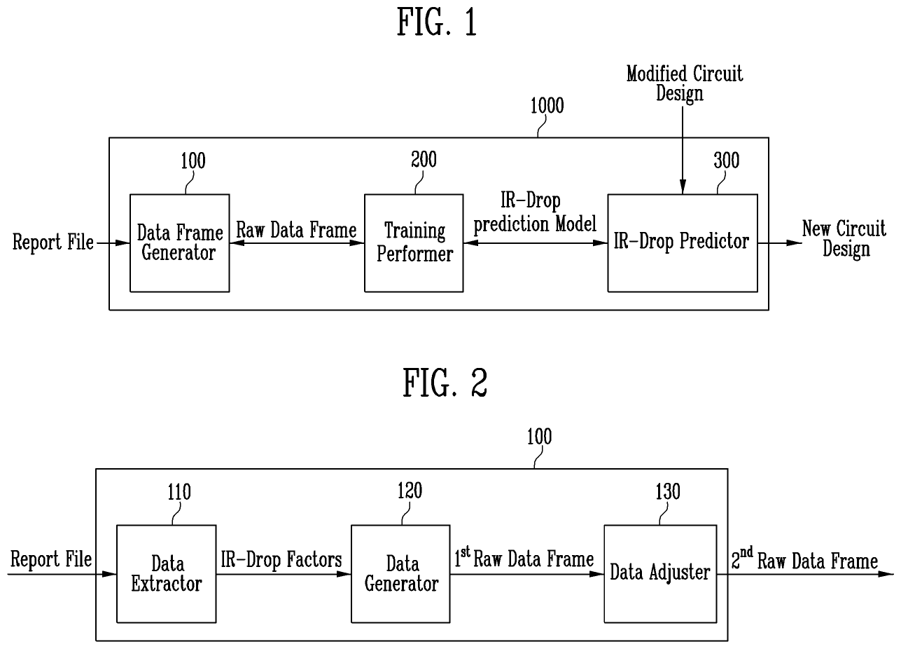

FIG. 1 is a block diagram illustrating an IR-drop prediction system according to an embodiment of the present disclosure.

Referring to FIG. 1, an IR-drop prediction system 1000 may include a data frame generator 100, a training performer 200, and an IR-drop predictor 300.

The data frame generator 100 may generate a raw data frame based on data received from outside of the system. The data received from the outside may be data obtained by predicting an IR-drop value with respect to a designed circuit, and the prediction of the IR-drop value may be performed using a software tool. The data obtained by predicting the IR-drop value with respect to the designed circuit may be referred to as a report file. The raw data frame may include IR-drop data for each of a plurality of instances in the designed circuit. In an embodiment, each of the instances may be a cell instance, which refers to an instance for a specific element in a circuit. The IR-drop data may include an IR-drop value corresponding to each of the instances and a plurality of IR-drop factors related to each IR-drop value. In addition, the IR-drop data may further include neighbor information indicating an influence from instances spatially adjacent to each of instances. Accordingly, the IR-drop data may include an IR-drop value, IR-drop factors, and neighbor information corresponding to each of the instances. The data frame generator 100 may provide the generated raw data frame to the training performer 200.

The training performer 200 may select input instances from among the plurality of instances included in the raw data frame received from the data frame generator 100. The input instances may be instances, from among the plurality of instances included in the raw data frame, in which IR-drop values are greater than or equal to a preset value. The training performer 200 may perform training for an IR-drop prediction based on the IR-drop data for the input instances. That is, the training performer 200 may input the IR-drop value, the IR-drop factors, and the neighbor information corresponding to each of the input instances to a training model in the training performer 200.

In an embodiment, the training performer 200 may perform training using a machine learning model for regression analysis. That is, the training performer 200 may perform training for closely predicting the IR-drop value based on the received IR-drop factors. In another embodiment, the training performer 200 may perform training using a machine learning model for classification analysis. That is, the training performer 200 may perform training for predicting with high accuracy whether an instance is a violated instance or a normal instance based on the received IR-drop factors. Here, the violated instance may be an instance in which the IR-drop value exceeds a preset value or conditions, and the normal instance may be an instance in which the IR-drop value is within a range of preset values or conditions. For example, if the IR-drop value of an instance exceeds 10% of an original voltage value, then the instance may be classified as the violated instance, and if the IR-drop value of an instance is within 10% of the original voltage value, then the instance may be classified as the normal instance. In an embodiment, the training performer 200 may perform training using both the machine learning model for regression and the machine learning model for classification.

The training performer 200 may perform learning using IR-drop data for a portion of the input instances to obtain an IR-drop prediction model, and may perform verification using IR-drop data for a remaining portion of the input instances, to verify performance of the obtained IR-drop prediction model. By repeating such a process, the training performer 200 may obtain an optimized IR-drop prediction model. The training performer 200 may provide the obtained IR-drop prediction model to the IR-drop predictor 300.

The IR-drop predictor 300 may predict an IR-drop based on the optimized IR-drop prediction model received from the training performer 200. For example, the IR-drop predictor 300 may receive information on a modified circuit design from outside of the system. The circuit design may be modified to decrease IR-drop values in violated instances. The modification of the circuit design may be performed based on the training result. For example, the IR-drop predictor 300 may predict the IR-drop based on the optimized IR-drop prediction model with respect to instances included in the circuit with the modified design, and thus the IR-drop predictor 300 may predict information on an IR-drop value corresponding to instances previously determined as violated instances. The information on the IR-drop value may be information indicating whether a violation will occur, or information indicating the IR-drop value itself. For example, the IR-drop predictor 300 may predict whether each of the instances in the design-modified circuit is a violated instance or a normal instance. Alternatively, the IR-drop predictor 300 may predict the IR-drop value for each of the instances in the design-modified circuit.

In an embodiment, according to the information on the IR-drop value for each of the instances in the design-modified circuit, the IR-drop predictor 300 may output the information on the design-modified circuit modified or provide information indicating that the circuit design should be additionally modified. For example, as a result of the prediction of the IR-drop predictor 300, if all instances in the design-modified circuit are determined as normal instances or have IR-drop values within a preset value range, then the IR-drop predictor 300 may be used to validate the corresponding circuit design as a new circuit design, and may output information on the new circuit design. As a result of the prediction of the IR-drop predictor 300, if at least a portion of the instances in the circuit of which the design is modified are determined as violated instances or have IR-drop values exceeding preset values or ranges, then the IR-drop predictor 300 may further modify the design-modified circuit. The IR-drop predictor 300 may repeat the modification of the circuit design until all instances in the design-modified circuit are determined as normal instances or have IR-drop values within the preset values or ranges. When all instances in the circuit are determined as normal instances or have IR-drop values within the preset values or ranges, the IR-drop predictor 300 may output the revised circuit design as a new circuit design and output information on the new circuit design. That is, new circuit design output by the IR-drop predictor 300 must only have instances that are normal instances or have IR-drop values within preset values or ranges.

FIG. 2 is a block diagram illustrating a data frame generator of FIG. 1.

Referring to FIG. 2, a data frame generator 100 may include a data extractor 110, a data generator 120, and a data adjuster 130. The data extractor 110 may receive data related to a designed circuit from the outside, which may be a report file that predicts the IR-drop value of the designed circuit using the software tool as described above with reference to FIG. 1. The software tool described above with reference to FIG. 1 may be, for example, a RedHawk Tool. In analyzing a circuit, the data extractor 110 may extract IR-drop factors for a plurality of instances from data received from the outside. As described above, the IR-drop factors may be factors that affect the IR-drop value of an instance.

The data generator 120 may generate a first raw data frame based on the IR-drop factors extracted by the data extractor 110. The first raw data frame may include the IR-drop data for each of the plurality of instances. As described above, the IR-drop data may include the IR-drop value, the IR-drop factors, and the neighbor information corresponding to each of the instances.

The data adjuster 130 may generate a second raw data frame by adjusting at least a portion of the IR-drop data included in the first raw data frame generated by the data generator 120. In an embodiment, the data adjuster 130 may adjust the neighbor information among the IR-drop data included in the first raw data frame. In an embodiment, the data adjuster 130 may sort the IR-drop data for the plurality of instances included in the first raw data frame according to the magnitude of the IR-drop value. For example, the data adjuster 130 may sort instances in the first raw data frame in a descending order so that the target instances are ordered from an instance having a large IR drop value to an instance having a small IR drop value.

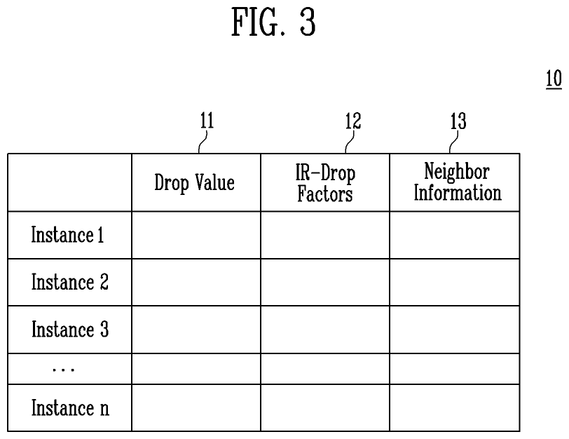

FIG. 3 is a diagram illustrating a raw data frame generated in an IR-drop prediction system according to an embodiment of the present disclosure.

Referring to FIGS. 1 and 3, a raw data frame 10 generated by a data frame generator 100 may include an IR-drop value 11, IR-drop factors 12, and neighbor information 13 corresponding to each of a plurality of instances for a circuit design.

The IR-drop value 11 may indicate an IR-drop value measured for each of the instances. The IR-drop factors 12 may be factors that affect the IR-drop value of each of the instances. The IR-drop factors 12 may be, for example, physical coordinates, a cell type, a cell toggle rate, leakage power, switching power, internal and clock pin power, total power, a leakage current, a total current, a clock pin toggle rate, an output capacitor, a pin capacitor, an input slew rate, and an output slew rate. The neighbor information 13 may be information that represents the influence of the instances spatially adjacent to each of the target instances listed in FIG. 3. In an embodiment, neighbor information on any one target instance may be expressed as information on tiles defined in an area spatially adjacent to the target instance. Here, each of the tiles spatially adjacent to the target instance may include one or more instances. More specifically, the neighbor information for the target instance may be expressed as IR-drop factors corresponding to each of the spatially adjacent tiles. Such IR-drop factors corresponding to each of the spatially adjacent tiles may include one or more of the exemplary IR-drop factors listed above. For example, the neighbor information corresponding to each of the tiles may be expressed as IR-drop factors such as a cell toggle rate, leakage power, switching power, internal and clock pin power, total power, a leakage current, a total current, and a clock pin toggle rate. In an embodiment, neighbor information for any given tile may be determined based on the IR-drop factors of the plurality of instances included in the tile. For example, a cell toggle rate for any one spatially adjacent tile may be determined based on cell toggle rates of all instances included for the corresponding spatially adjacent tile. More specifically, the cell toggle rate for the corresponding spatially adjacent tile may be determined by using a method of summing the cell toggle rates of all of the instances included in the corresponding spatially adjacent tile with weights or obtaining an average value of the cell toggle rates of the instances included in the corresponding spatially adjacent tile.

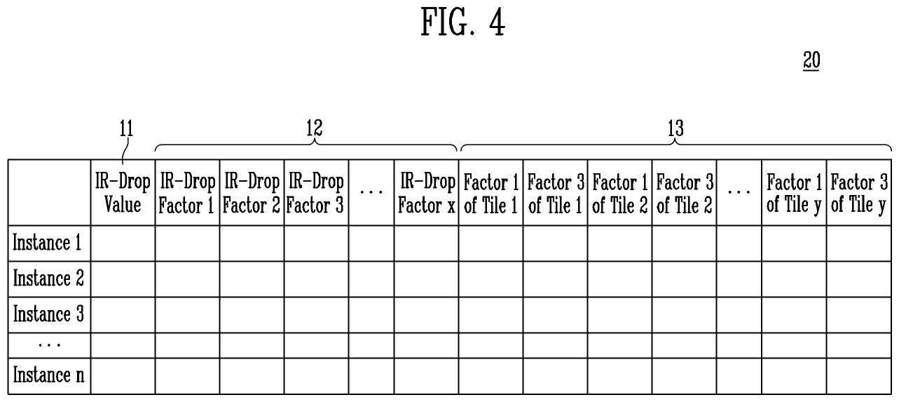

The raw data frame 10 may be structured so that the target instances are sorted into rows and the IR-drop value 11, the IR-drop factors 12, and the neighbor information 13 corresponding to each of the instances are sorted by instance and divided into columns. As described above, the raw data frame 10 may be divided into the first raw data frame and the second raw data frame. The first raw data frame and the second raw data frame will be described in more detail with reference to FIGS. 4 to 8 below.

FIG. 4 is a diagram illustrating an example of a first raw data frame generated in an IR-drop prediction system according to an embodiment of the present disclosure.

Referring to FIGS. 2 to 4, a data generator 120 may generate a first raw data frame 20. The first raw data frame 20 may include, corresponding to each of a plurality of instances, an IR-drop value 11, IR-drop factors 12, and neighbor information 13.

The IR-drop factors 12 may be factors that affect the IR-drop value 11 of each of the instances. The IR-drop factors 12 may be included in the first raw data frame 20 shown in FIG. 4, in which the IR-drop factors 12 are divided into an x number of columns.

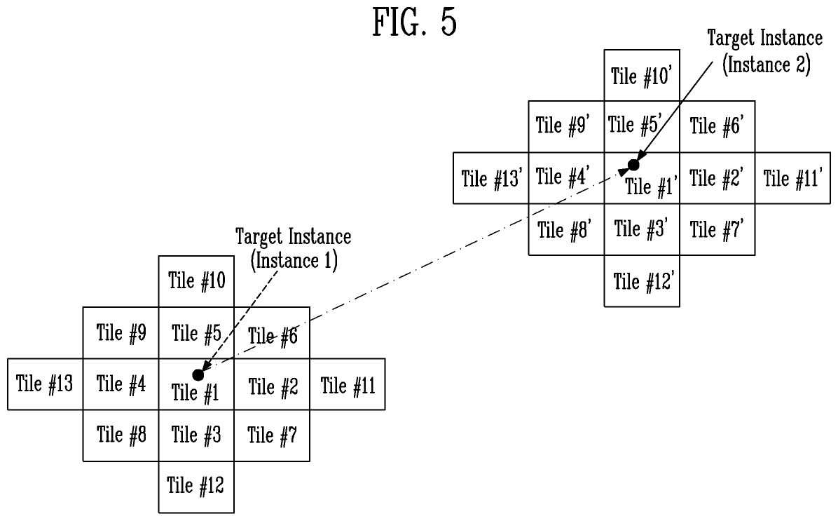

The neighbor information 13 may be expressed as IR-drop factors for one or more tiles defined in an area spatially adjacent to the target instance, and the IR-drop factors for the tiles may include at least a portion of the IR-drop factors 12 for the instances. The neighbor information 13 of the first raw data frame 20 shown in FIG. 4 may include information on a y number of tiles. Neighbor information for each of the y number of tiles, may include information on a factor 1 and a factor 3 from the x number of IR-drop factors 12. Accordingly, the neighbor information 13 of the first raw data frame 20 may include a factor 1 and a factor 3 for a tile 1, a factor 1 and a factor 3 for a tile 2, . . . , and a factor 1 and a factor 3 for a tile y. The neighbor information for the combinations of factor and tile are divided into columns. Tiles will be described in more detail with reference to FIG. 5 below.

FIG. 5 is a diagram illustrating tiles used to generate a data frame in an IR-drop prediction system according to an embodiment of the present disclosure.

Referring to FIGS. 2, 4, and 5, an area around a target Instance 1 of FIG. 3, for example, may be divided into 13 tiles (Tile #1 to Tile #13). The tile including the target instance may be defined as the tile 1 (Tile #1), and the tile 2 (Tile #2) to the tile 13 (Tile #13) may be defined based on their proximity to the tile 1 (Tile #1). In an embodiment, each of the adjacent tiles, including Tile #1 that contains the target instance, may include one or more instances distinct from the target instance.

When generating a first raw data frame 20, a data generator 120 may generate neighbor information 13 for the adjacent tiles in FIG. 5. As described above, the neighbor information 13 may be expressed as IR-drop factors for each of the adjacent tiles. In an embodiment, the IR-drop factors for each of the adjacent tiles may be determined based on the IR-drop factors for all of the instances corresponding to each of the tiles.

When the target instance is an Instance 2, tiles (Tile #1′ to Tile #13′) may be newly set according to a position of the Instance 2. In an embodiment, a size and the number of adjacent tiles may be the same even though the location of the target instance varies. That is, the adjacent tiles of the Instance 2 may be positioned in a layout that is substantially the same as that of the adjacent tiles of the Instance 1. Thus, the definition of an area spatially adjacent to the target instance remains the same with respect to the tiles after translation of the target instance from the position of Instance to the position of Instance 2.

The number and size of tiles considered when generating the neighbor information 13 for the first raw data frame 20 may be preset values. However, as will be described later, the number and size of tiles may be adjusted when a second raw data frame and an input data frame are generated.

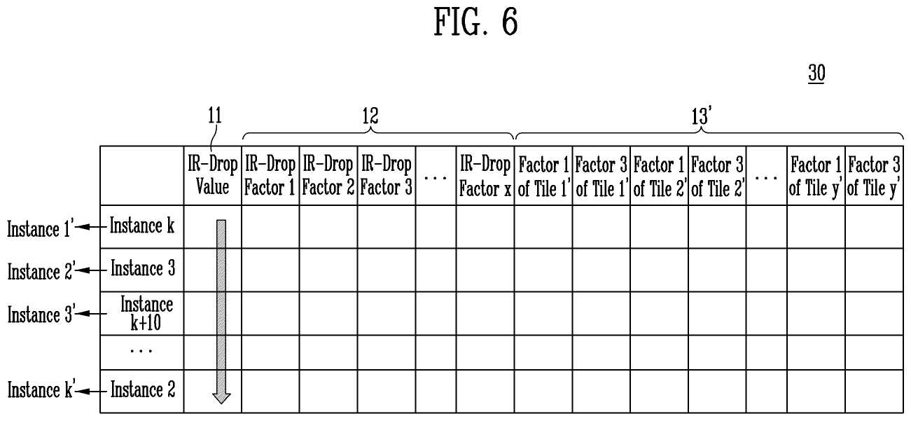

FIG. 6 is a diagram illustrating an example of a second raw data frame generated in an IR-drop prediction system according to an embodiment of the present disclosure.

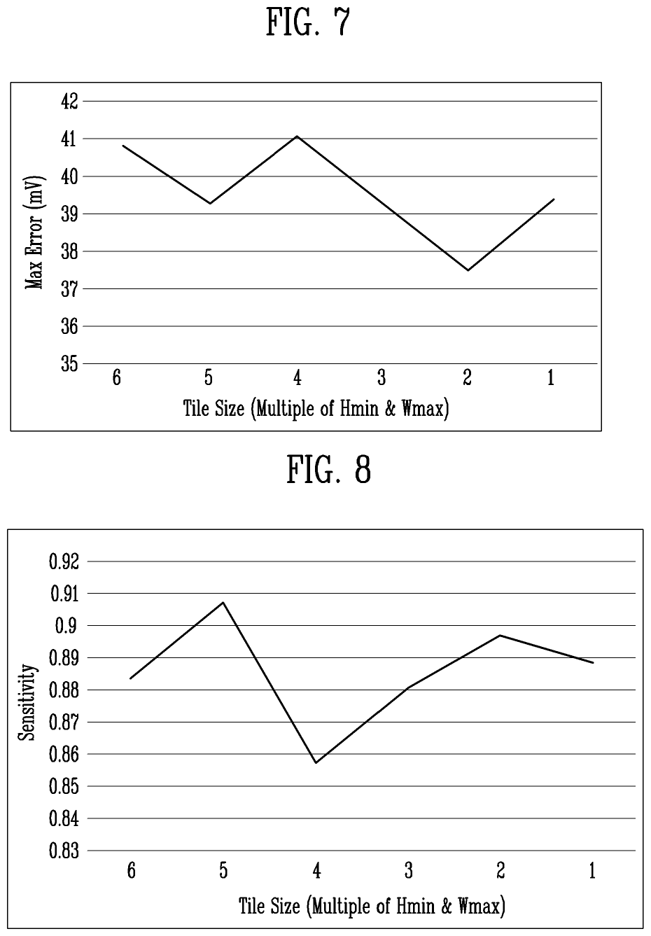

Referring to FIGS. 2 to 6, a data adjuster 130 may generate a second raw data frame 30 based on a first raw data frame 20 generated by the data generator 120. In an embodiment, the data adjuster 130 may adjust the size of the tiles described with reference to FIG. 5. When the size of the tiles is adjusted, the instances included in each of the tiles may change, and thus the IR-drop factors for each of the target tiles and adjacent tiles may change. Accordingly, neighbor information 13′ included in the second raw data frame 30 may be different from neighbor information 13 included in the first raw data frame 20. The size of a tile may be adjusted based on performance indicators of the machine learning model included in the training performer 200. The adjustment of the size of a tile will be described in detail with reference to FIGS. 7 and 8 below. In addition, when considering the tiles shown in FIG. 5, the number y of tiles may be 13.

In an embodiment, the data adjuster 130 may sort the instances according to the magnitude of the IR-drop values for the target tile. That is, the instances and the IR-drop data corresponding thereto may be sorted according to the order of IR-drop value. In an embodiment, the data adjuster 130 may sort the instances in the second raw data frame 30 in a descending order so that the instances are arranged from an instance having a large IR drop value to an instance having a small IR drop value.

The instances in the second raw data frame 30 may be re-labeled according to the sorted order. For example, a previously defined Instance k may be newly defined as an Instance 1′; a previously defined Instance 3 may be newly defined as an Instance 2′; a previously defined Instance k+10 may be newly defined as an Instance 3′; and a previously defined Instance 2 may be newly defined as an Instance k′.

FIG. 7 is a graph illustrating an example of a method of determining a size of a tile in an IR-drop prediction system according to an embodiment of the present disclosure.

FIG. 8 is a graph illustrating another example of a method of determining a size of a tile in an IR-drop prediction system according to an embodiment of the present disclosure.

Referring to FIGS. 5, 7, and 8, a performance indicator of a machine learning model may vary according to tile size. The performance indicator of the machine learning model may be, for example, errors such as a max error, a mean absolute error (MAE), and a root mean square error (RMSE), accuracy, precision, sensitivity, and others. A data adjuster 130 may determine a size of a tile used in generation of a second raw data frame 30 based on the performance indicator of the machine learning model. The size of the tile may be expressed as a multiple of a maximum width Wₘₐₓ and a minimum height Hₘᵢₙ, among dimensions of all instances included in a first raw data frame 20.

Referring to FIG. 7, as an example the maximum error value mV is lowest when the size of the tile is twice combination of the maximum width Wₘₐₓ and the minimum height Hₘᵢₙ. In addition, referring to FIG. 8, sensitivity is at a maximum when the size of the tile is 5 times combination of the maximum width Wₘₐₓ and the minimum height Hₘᵢₙ. In FIGS. 7 and 8, only the maximum error and the sensitivity according to the tile size are illustrated, but other performance indicators may also be used or considered in practicing the method.

The data adjuster 130 may set an optimal tile size in consideration of the performance indicators of the machine learning model according to tile size. The data adjuster 130 may observe each of performance indicators while changing the tile size within a predetermined range, and may determine the tile size in consideration of the performance indicators and the performance required in the IR-drop prediction system 1000. In embodiments, tile size is repeatedly adjusted and an optimal tile size may be determined by referring to convexity and concavity in each graph of the performance indicators from evaluation all of the adjusted tile sizes.

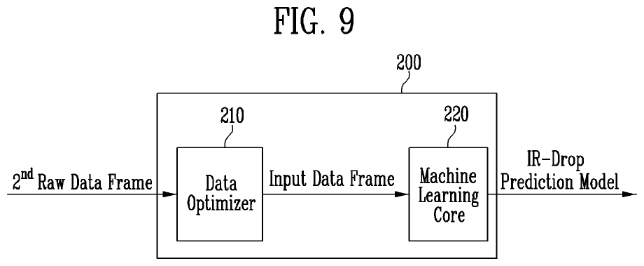

FIG. 9 is a block diagram illustrating a training performer of FIG. 1.

Referring to FIGS. 1, 2, 5, 6, and 9, a training performer 200 may include a data optimizer 210 and a machine learning core 220. The data optimizer 210 may receive a second raw data frame 30 from a data frame generator 100 and generate an input data frame based on the second raw data frame 30. In an embodiment, the data optimizer 210 may generate the input data frame by selecting input instances from among the plurality of instances included in the second raw data frame 30. In addition, in an embodiment, the data optimizer 210 may generate the input data frame by determining, for the input data, the neighbor information 13′ of the second raw data frame 30 to be used based on the number and/or location of adjacent tiles to be considered, i.e., some of the neighbor information 13′ may not be used in generating the input data frame. The data optimizer 210 may determine the number of tiles to be included in the input instances and the input data frame based on the performance indicators of the machine learning model included in the machine learning core 220.

Accordingly, the input data frame may include the IR-drop data for the input instances, and more specifically, may include the IR-drop value, the IR-drop factors, and select neighbor information for the input instances.

As the input instances are selected by the data optimizer 210, the number of instances included in the input data frame may be different from the number of instances included in the second raw data frame 30. More specifically, the number of instances included in the input data frame may be less than the number of instances included in the second raw data frame 30. In addition, as the number of tiles is adjusted by the data optimizer 210, the number of neighbor information included in the input data frame may be different from the number of neighbor information included in the second raw data frame 30. More specifically, the number of neighbor information included in the input data frame may be less than the number of neighbor information included in the second raw data frame 30.

In addition, in an embodiment, the data optimizer 210 may randomize an order in which the input instances are input to the machine learning model. For example, the data optimizer 210 may provide the machine learning core 220 with a plurality of input data frames, in which each of the input instances contains the same data, but the order of the input instances is changed in each input data frame. The machine learning core 220 may obtain a training result by repeatedly performing training based on the plurality of input data frames. Accordingly, errors that may result of training using a fixed order of input instances in input data frames may be reduced when input instances are input to the machine learning model.

The machine learning core 220 may perform training by inputting the input data frame provided from the data optimizer 210 to the machine learning model. The machine learning model may include one or more selected of a machine learning model for regression and a machine learning model for classification. For example, the machine learning model may use a gradient boosting model (gradient boosting algorithm (GBTM)) such as XGBoost, LightGBM, or CatBoost, but the models are not limited thereto. In some embodiments, the machine learning core 220 may perform learning using the IR-drop data for a portion of the instances included in the input data frame, and may perform verification using the IR-drop data for the remaining portion of the instances included in the input data frame.

The machine learning core 220 may obtain an IR-drop prediction model according to a result of training, and may provide the IR-drop prediction model to an IR-drop predictor 300.

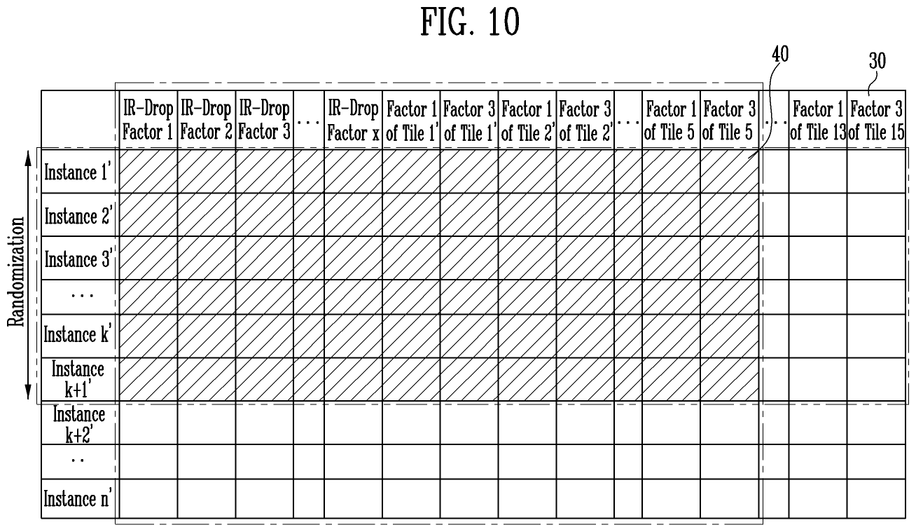

FIG. 10 is a diagram illustrating an example of an input data frame generated in an IR-drop prediction system according to an embodiment of the present disclosure.

Referring to FIGS. 1, 2, 5, 6, 9, and 10, a data optimizer 210 may generate an input data frame 40 based on a second raw data frame 30 received from a data frame generator 100.

As described with reference to FIG. 6, the plurality of instances included in the second raw data frame 30 may be sorted according to the magnitude of the IR-drop value. In an embodiment, the data optimizer 210 may select a portion of a plurality of instances (e.g., Instance 1′ to Instance n′) included in the second raw data frame 30 as input instances. The input instances may be instances having IR-drop values greater than or equal to a preset value. From among all of the plurality of instances (Instance 1′ to Instance n′) included in the second raw data frame 30, the remaining instances may have an IR-drop value that is less than the preset value. Assuming that the plurality of instances (Instance 1′ to Instance n′) included in the second raw data frame 30 in FIG. 10 are sorted in a descending order according to the size of the IR-drop value, an Instance k+1′ may have an IR-drop value closest to the preset value and Instance 1′ to Instance k′ may have IR-drop values greater than that of the Instance k+1′. In addition, the IR-drop values of Instance k+2′ to Instance n′ may be less than the preset value.

As an example, the preset value may be a boundary value at which the instances are determined as violations. In other examples, the preset value may be less than or greater than the boundary value at which the instances are determined as violations. When the preset value is less than the boundary value at which the instances are determined as violations, for example, selected instances may include all instances having IR-drop values that are determined as violations.

In an embodiment, the data optimizer 210 may determine the number of tiles to be considered in the input data frame from among the total number tiles associated with a neighbor information 13′ of the second raw data frame 30. Assuming a configuration illustrated in FIG. 5, the neighbor information 13′ of the second raw data frame 30 may include IR-drop factors for tiles 1 to 13. The data optimizer 210 may select only IR-drop factors for some of the tiles, for example, may select only 5 tiles. That is, the data optimizer 210 may determine to include only IR-drop factors of tiles 1 to 5 of the neighbor information 13′ of the second raw data frame 30 in the input data frame 40. In an embodiment, as the distance from the target instance increases from a tile 1 to a tile 13, and the input data frame 40 may select tiles relatively adjacent to the target instance among the tiles.

Accordingly, the input data frame 40 may include IR-drop data for the Instance 1′ to the Instance k+1′, and the IR-drop data includes a IR drop value, voltage drop factors, and neighbor information for each of input instances (Instance 1′ to Instance k+1′). In addition, the neighbor information included in the input data frame 40 may include only IR-drop factors of the tile 1 to the tile 5.

In addition, in an embodiment, the data optimizer 210 may randomize an order in which the input instances (Instance 1′ to Instance k+1′) are input to the machine learning model. Accordingly, an order of the instances included in the input data frame 40 may be randomized regardless of the IR drop value, which is different from the second raw data frame 30 in which the instances are sorted according to the IR drop value.

If a first raw data frame 20 or a second raw data frame 30 is input to the machine learning model without separate processing, since the size of the data frame is excessively large, a time required for training is excessively long. In addition, since an error in regression analysis may increase or precision and sensitivity in classification analysis may decrease, obtaining desired machine learning performance may be difficult.

The IR-drop prediction system 1000 according to an embodiment of the present disclosure can reduce a time required for training by adjusting the size of the data frame, and can improve IR-drop prediction performance by flexibly controlling the size of the data frame to suit the desired machine learning performance.

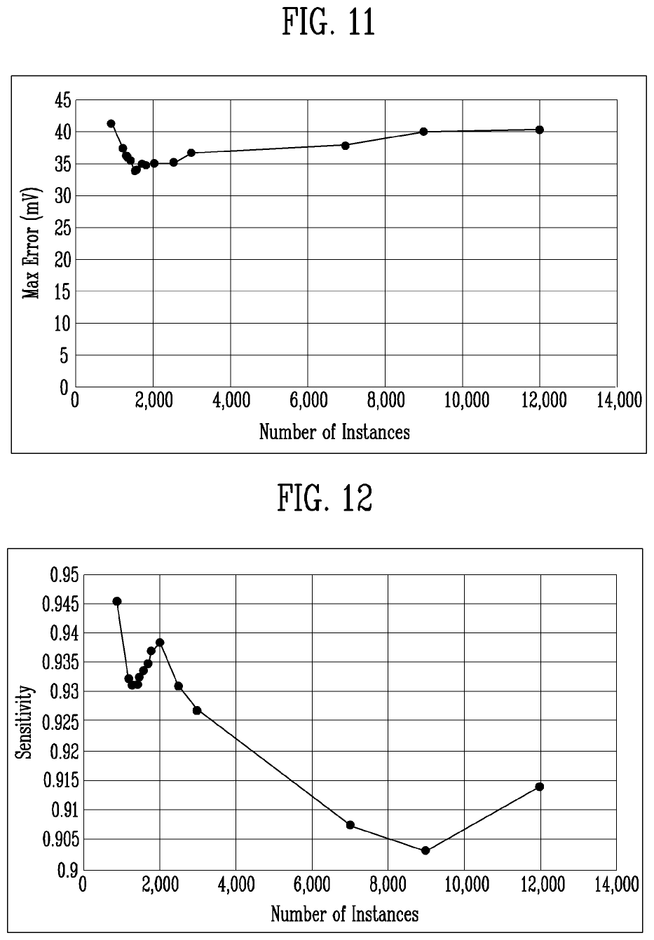

FIG. 11 is a graph illustrating an example of a method of selecting an instance included in an input data frame in an IR-drop prediction system according to an embodiment of the present disclosure.

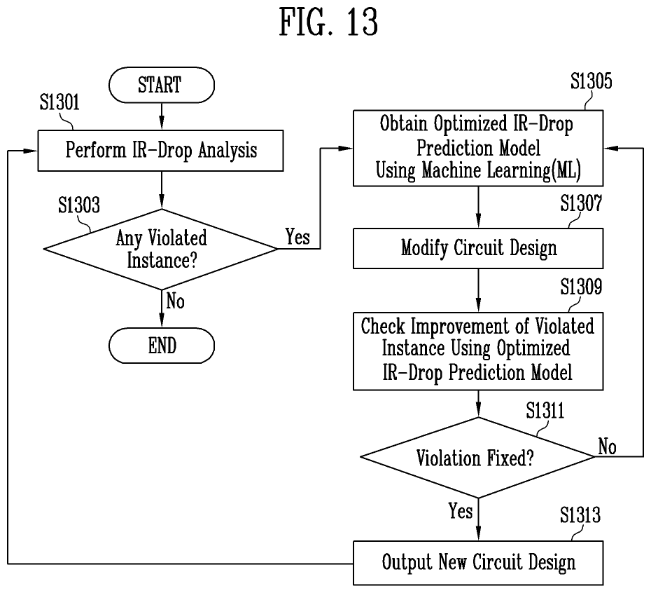

FIG. 12 is a graph illustrating another example of a method of selecting an instance included in an input data frame in an IR-drop prediction system according to an embodiment of the present disclosure.

Referring to FIGS. 10 to 12, performance indicators of the machine learning models may vary according to the number of instances. The performance indicator of the machine learning model may be, for example, errors such as a maximum error, a mean absolute error (MAE), of a root mean square error (RMSE), accuracy, precision, sensitivity, and others.

Referring to FIG. 11, the maximum error may be a minimum when the number of input instances is around 1500. Referring to FIG. 12, the sensitivity may be at a maximum when the number of input instances is around 1000. In FIGS. 11 and 12, only the maximum error and the sensitivity according to the number of input instances are checked, but other performance indicators may be further considered.

The data optimizer 210 may set the optimal number of input instances in consideration of the performance indicators of the machine learning model according to the number of input instances. The data optimizer 210 may observe each of the performance indicators while changing the number of input instances within a predetermined range, and may determine the number of input instances in consideration of the performance indicators according thereto and performance required in the IR-drop prediction system 1000. The optimal number of input instances may be determined by referring to convexity and concavity in a graph of each of the desired performance indicators according to the number of input instances.

In addition, although not shown in FIGS. 11 and 12, the data optimizer 210 may set the optimal number of tiles based on the performance indicators of the machine learning model according to the number of tiles available in the input data frame 40. The data optimizer 210 may observe each of the performance indicators while changing the number of tiles within a predetermined range, and may determine the number of tiles to be considered in the input data frame 40 in consideration of the performance indicators according thereto and performance required in the IR-drop prediction system 1000. The optimal number of tiles may be determined by referring to convexity and concavity in a graph of each of the selected performance indicators according to the number of tiles.

FIG. 13 is a flowchart illustrating an IR-drop prediction method according to an embodiment of the present disclosure.

Referring to FIG. 13, IR-drop analysis may be performed in an operation S1301, and for example, the IR-drop analysis may be performed by obtaining a voltage profile using software such as RedHawk Tool.

In an operation S1303, as a result of the IR-drop analysis, it may be checked whether the violated instances having the IR-drop value determined as a violation exist. When the violated instances exist, an optimized IR-drop prediction model may be obtained using machine learning in an operation S1305. The IR-drop prediction model may be obtained by inputting the data frame generated based on the IR-drop analysis result of the operation S1301 to the machine learning model.

The circuit design may be modified in an operation S1307, and whether the violated instances determined as violations in the existing circuit are improved can be checked in the circuit of which the design is modified in an operation S1309, by using the IR-drop prediction model obtained in the operation S1305. As the design of the circuit is modified, if the violated instances are classified as a non-violation by the IR-drop prediction model or the IR-drop value of the violated instances is predicted to be less than or equal to a predetermined value, then it may be determined that the violation of the violated instances are cured in an operation S1311. If it is predicted that at least a portion of the violated instances is not cured in the operation S1311, then the design of the circuit may be further modified by returning to the operation S1307. These steps may be repeated until the violation of all violated instances is cured, and when it is predicted that the violation of all violated instances is corrected in the operation S1311, the modified circuit design may be determined as a new circuit design and information on the new circuit design may be output in an operation S1313. According to the new circuit design, the instances in the circuit may be configured as the normal instances having the IR-drop values that are not determined as violations. Returning to the operation S1301, the IR-drop analysis may be performed based on the new circuit design determined in the operation S1311. As a result of the IR-drop analysis, if it is determined that the violated instances do not exist anymore in the operation S1303, the operations may be ended.

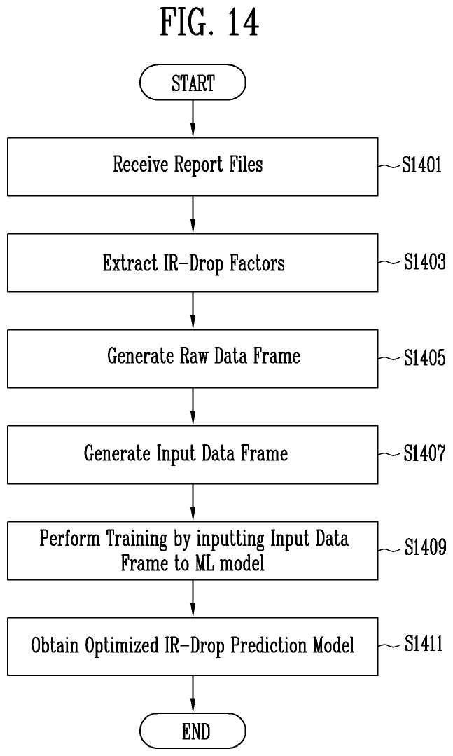

FIG. 14 is a flowchart illustrating an operation S1305 of FIG. 13 in more detail.

Referring to FIGS. 1, 13, and 14, in an operation S1401, a data frame generator 100 of an IR-drop prediction system 1000 may receive a report file from the outside. The report file may include data related to an IR-drop analysis result according to the operation S1301.

In an operation S1403, the data frame generator 100 of the IR-drop prediction system 1000 may extract IR-drop factors from the report file, and in an operation S1405, the data frame generator 100 may generate a raw data frame based on the extracted IR-drop factors. The raw data frame may include the IR-drop data for each of the plurality of instances, and the IR-drop data may include the IR-drop value for each of the instances and the IR-drop factors related to the IR-drop value. In addition, the IR-drop data may further include neighbor information. The neighbor information may indicate the influence of the instances spatially adjacent to each of the target instances, and in an embodiment, the neighbor information on any one target instance may be expressed as the information on the tiles defined in the area spatially adjacent to the target instance.

In an operation S1407, a training performer 200 of the IR-drop prediction system 1000 may generate an input data frame based on the raw data frame of the operation S1405. The input data frame may be generated by selecting the input instances among the plurality of instances included in the raw data frame, and thus the input data frame may include the IR-drop data for the input instances. In an embodiment, the input instances may be instances in which the IR-drop values are greater than or equal to the preset value among the instances included in the raw data frame. In addition, in an embodiment, when generating the input data frame, only a portion of the neighbor information included in the raw data frame may be selected by adjusting the number of tiles.

In an operation S1409, the training performer 200 of the IR-drop prediction system 1000 may perform training by inputting the input data frame of the operation S1407 to the machine learning model, and thus the optimized IR-drop prediction model may be obtained in an operation S1411. The obtained IR-drop prediction model may be provided to the IR-drop predictor 300 of the IR-drop prediction system 1000, and thus the operations S1307 to S1311 of FIG. 13 may be performed.

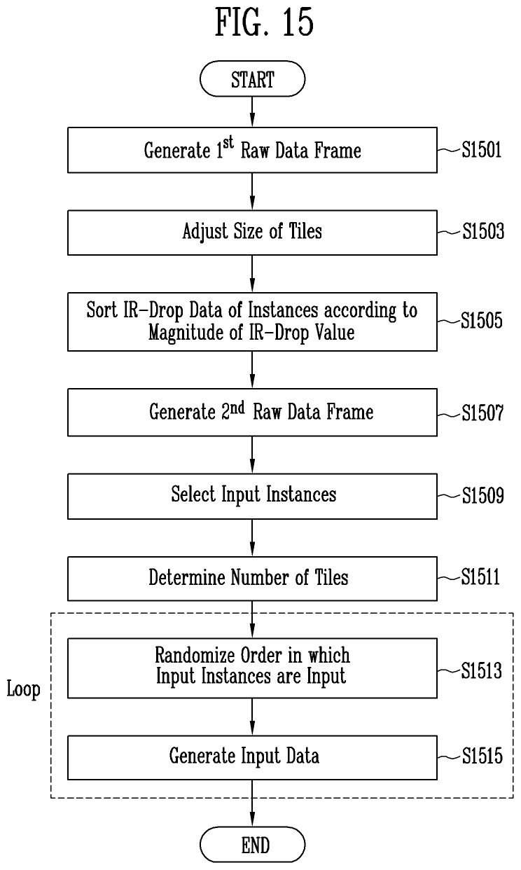

FIG. 15 is a flowchart illustrating the operations S1405 and S1407 of FIG. 14 in more detail.

Referring to FIGS. 1 and 13 to 15, in an operation S1501, a data frame generator 100 of an IR-drop prediction system 1000 may generate a first raw data frame. The first raw data frame may include IR-drop data for each of a plurality of instances. The IR-drop data may include the IR-drop value for each of the instances, the plurality of IR-drop factors related to the IR-drop value, and IR-drop factors for the above-described tiles.

In an operation S1503, the data frame generator 100 of the IR-drop prediction system 1000 may adjust the size of a tile. The performance indicators of the machine learning model may vary according to the size of the tile, and the data frame generator 100 may determine an optimal tile size by considering the performance indicators.

In addition, in an operation S1505, the data frame generator 100 of the IR-drop prediction system 1000 may sort the instances according to the magnitude of the IR-drop value for each of the instances. For example, the instances may be sorted in a descending order according to the magnitude of the IR-drop value.

Accordingly, a second raw data frame may be generated in an operation S1507. As the tile size is adjusted in the operation S1503, the neighbor information of the second raw data frame may be different from that of the first raw data frame, and as the order of the instances is sorted in the operation S1505, the order of the instances in the second raw data frame may be different from that of the first raw data frame.

In an operation S1509, the training performer 200 of the IR-drop prediction system 1000 may select the input instances among the instances included in the second raw data frame, and the input instances may be the instances of which the IR-drop values are greater than or equal to the preset value.

In an operation S1511, the training performer 200 of the IR-drop prediction system 1000 may determine the number of tiles to be considered when generating the input data. That is, the training performer 200 may select a portion of the information on the tiles included in the second raw data frame, and the information on the selected tiles may be included in the input data frame.

In an operation S1513, the training performer 200 of the IR-drop prediction system 1000 may randomize an input order of the input instances. Here, the input order may mean an order in which the input instances are input to the training model.

Accordingly, the input data frame may be generated in an operation S1515. As the input instances are selected in the operation S1509, the number of instances included in the input data frame may be less than the number of instances included in the second raw data frame. In addition, as the number of tiles to be considered when generating the input data is selected in the operation S1511, the number of IR-drop factors of the tiles included in the input data frame may be less than the number of IR-drop factors of the tiles included in the second raw data frame. In addition, as the input order of the input instances is randomized in the operation S1513, the order of the instances included in the input data frame may be different from the order of the instances included in the second raw data frame.

In an embodiment, the operations S1513 and S1515 may be repeatedly performed, and thus a plurality of input data frames may be generated. When generating the plurality of input data frames, the operation S1513 of randomizing the input order of the input instances may also be repeatedly performed, and thus orders of input instances in different data frames among the plurality of input data frames may be different.

What is claimed is:

1. An IR-drop prediction system comprising:
a data frame generator configured to generate a raw data frame including IR-drop data for each of a plurality of instances in a designed circuit;
a training performer configured to select input instances among the plurality of instances included in the raw data frame and perform training for an IR-drop prediction based on the IR-drop data for the input instances; and
an IR-drop predictor configured to predict an IR-drop based on an IR-drop prediction model obtained according to a result of the training,
wherein the IR-drop data includes an IR-drop value of a corresponding instance and a plurality of IR-drop factors related to the IR-drop value, and
the input instances have IR-drop values greater than or equal to a preset value.

2. The IR-drop prediction system of claim 1, wherein the IR-drop data further includes neighbor information of instances spatially adjacent to the corresponding instance.

3. The IR-drop prediction system of claim 2, wherein the neighbor information is arranged into a plurality of tiles defined in an area that includes spatially adjacent instances.

4. The IR-drop prediction system of claim 3, wherein the neighbor information for a tile includes IR-drop factors.

5. The IR-drop prediction system of claim 4, wherein the neighbor information for each of the plurality of tiles is determined based on the IR-drop factors of the spatially adjacent instances included in each corresponding tile.

6. The IR-drop prediction system of claim 5, wherein the data frame generator comprises:
a data extractor configured to extract IR-drop factors for the plurality of instances from data received from an outside;
a data generator configured to generate a first raw data frame including IR-drop data for each of the plurality of instances based on the IR-drop factors; and
a data adjuster configured to generate a second raw data frame by adjusting at least a portion of the IR-drop data included in the first raw data frame.

7. The IR-drop prediction system of claim 6, wherein the data adjuster adjusts sizes of the plurality of tiles based on performance indicators of a machine learning model included in the training performer.

8. The IR-drop prediction system of claim 6, wherein the data adjuster sorts the IR-drop data for the plurality of instances included in the first raw data frame according to a magnitude of the IR-drop value.

9. The IR-drop prediction system of claim 6, wherein the training performer comprises:
a data optimizer configured to generate an input data frame by determining the number of the input instances and tiles; and
a machine learning core configured to perform training by inputting the input data frame to a machine learning model included in the training performer.

10. The IR-drop prediction system of claim 9, wherein the data optimizer determines the number of the input instances and the tiles based on performance indicators of the machine learning model.

11. The IR-drop prediction system of claim 10, wherein the data optimizer randomizes an order in which the input instances are input to the machine learning model.

12. The IR-drop prediction system of claim 9, wherein the machine learning core performs learning using a portion of the input instances and performs verification using the remaining portion.

13. The IR-drop prediction system of claim 1, wherein the IR-drop predictor predicts information on an IR-drop value that is changed as a design of the circuit is modified with respect to violated instances determined as a violation by the IR-drop predictor.

14. The IR-drop prediction system of claim 13, wherein the IR-drop predictor outputs design information on the circuit of which the design is modified according to the information on the changed IR-drop value corresponding to the violated instances.

15. The IR-drop prediction system of claim 14, wherein in the circuit of which the design is modified, normal instances determined as a non-violation by the IR-drop predictor are included.

16. An IR-drop prediction method comprising:
generating a raw data frame including IR-drop data for each of a plurality of instances in a designed circuit;
generating an input data frame including IR-drop data for input instances by selecting the input instances from among the plurality of instances included in the raw data frame;
performing training by inputting the input data frame to a machine learning model; and
obtaining an optimized IR-drop prediction model based on a result of the training,
wherein the IR-drop data includes an IR-drop value of a corresponding instance and a plurality of IR-drop factors related to the IR-drop value, and
the input instances have IR-drop values greater than or equal to a preset value.

17. The IR-drop prediction method of claim 16, wherein the IR-drop data further includes information on a plurality of tiles defined in an area with at least one of instance that is spatially adjacent to the corresponding instance, and
the information includes IR-drop factors corresponding to each of the plurality of tiles.

18. The IR-drop prediction method of claim 17, wherein generating the raw data frame comprises:
generating a first raw data frame including the IR-drop data for each of the plurality of instances by extracting the IR-drop factors for the plurality of instances from data on the circuit received from an outside; and
generating a second raw data frame in which IR-drop data for the tiles included in the first raw data frame is changed by adjusting sizes of the plurality of tiles.

19. The IR-drop prediction method of claim 18, wherein generating the input data frame comprises selecting a portion of the information on the plurality of tiles by selecting a portion of the plurality of tiles used in the second raw data frame.

20. The IR-drop prediction method of claim 16, further comprising:
predicting information on an IR-drop value according to modifying a design of the circuit with respect to violated instances having IR-drop values determined as a violation from among the plurality of instances.
